(19) United States
(12) Patent Application Publication
(10) Pub. No.: US 2005/0079679 A1
(43) Pub. Date: Apr. 14, 2005

(54) Trench capacitor and method for fabricating a trench capacitor

(75) Inventors: Harald Seidl, Poering (DE); Annette Sanger, Dresden (DE); Stephan Kudelka, Ottendorf-Okrilla (DE); Martin Gutsche, Dorfen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: Infineon Technologies AG

(21) Appl. No.: 10/920,808

(22) Filed: Aug. 18, 2004

(30) Foreign Application Priority Data
Aug. 18, 2003 (DE) 103 37 858.8

(51) Int. Cl. H01L 27/108

(52) U.S. Cl. 438/386

(57) ABSTRACT

A method for fabricating a trench capacitor in a semiconductor substrate with a low-impedance inner electrode for use in memory cells of memory devices. A separating layer is provided on a dielectric layer in the active region of the trench capacitor. Afterward, a low-impedance inner electrode made of metal or a metal compound is introduced both in the active region and in the collar region lined with an insulation layer.

### CROSS-REFERENCE TO RELATED APPLICATIONS

This Utility Patent Application claims priority to German Patent Application No. DE 103 37 858.8, filed on Aug.18, 2003, which is incorporated herein by reference.

### BACKGROUND

The invention relates to a method for fabricating a trench capacitor in a semiconductor substrate. A hole trench is introduced into the semiconductor substrate from a substrate surface and an outer electrode is provided in sections of the semiconductor substrate that join the hole trench. The hole trench is lined with a dielectric layer in an active region reaching into the semiconductor substrate and with an insulation layer in a collar region arranged between the substrate surface and the active region. The invention additionally relates to a trench capacitor.

A concern in the fabrication of semiconductor circuit devices such as DRAM (Dynamic Random Access Memory) memory devices, for example, is to increase the integration density. In such case, it is attempted to increase the number of switching elements or memory cells to be formed per unit area in a semiconductor substrate in order to be able to achieve circuits, in particular semiconductor memories, that are as small, compact and powerful as possible.

Many semiconductor circuit devices require capacitor structures, for example in a DRAM memory device comprising memory cells that are connected to one another via addressing lines. A DRAM memory cell usually contains a storage capacitor, which is connected to a selection transistor and stores a digital information item in the form of a charge state. The storage capacitors are often provided in the form of trench capacitors formed in a hole trench in a semiconductor substrate. Usually, in order to form a trench capacitor, a hole trench is etched into the semiconductor substrate from a substrate surface. Either during or after the etching of the hole trench, an oxide collar is formed in a region of the hole trench that adjoins the substrate surface, referred to in this case as collar region. The oxide collar prevents a formation of a parasitic field-effect transistor. The outer electrode of such a trench capacitor is usually produced by indiffusion of arsenic into the semiconductor substrate.

As an alternative, a buried doped layer, when using a p-type substrate an n⁺-type layer, which is referred to as “buried plate” is provided as the outer electrode. In the hole trench, the storage dielectric is deposited below the collar region and an inner electrode formed as a counterelectrode is deposited onto the storage dielectric. The inner electrode generally comprises a polycrystalline semiconductor material which fills a cavity remaining after the deposition of the storage dielectric. In the collar region, the inner electrode is etched back in sections and connected to the assigned selection transistor of the DRAM memory cell via a connection region, which is usually formed as a doped zone buried in the semiconductor substrate. When using the trench capacitor in a DRAM memory cell, the charge is stored in the inner electrode.

It is a matter of interest to lower the nonreactive resistance of the inner electrode of the trench capacitor, particularly if the trench capacitor is used for fabricating a semiconductor memory device. At the present time, the inner electrode comprises doped polysilicon having a resistance in a range below 1000×10⁻⁶ ohms/cm. Since the resistance depends on the cross-sectional area of a conductor, a further miniaturization of the trench capacitor structure and thus also of the inner electrode leads to a very high nonreactive resistance of the inner electrode and the lead to the electrically active section of the inner electrode below the collar region.

Proposals for providing the inner electrode from a low-impedance material, such as metal or metal compounds, for example, have the disadvantage that a direct contact between the metal and the storage dielectric leads to chemical reactions that damage the dielectric. Therefore, it has been customary for only the collar region of the hole trench to be filled with a metal and for the active region of the trench capacitor that contains the storage dielectric still to be provided with a polysilicon filling.

### SUMMARY

One embodiment of the present invention provides a method for fabricating a trench capacitor with an inner electrode comprising a low-impedance material. Moreover, the invention provides a trench capacitor with a low-impedance inner electrode.

In one embodiment, a method for fabricating a trench capacitor in a semiconductor substrate is provided in which a hole trench is introduced into the semiconductor substrate from a substrate surface and an outer electrode is provided in sections of the semiconductor substrate that join the hole trench. The hole trench is lined with a dielectric layer in an active region reaching into the semiconductor substrate and with an insulation layer in a collar region arranged between the substrate surface and the active region. According to one embodiment of the invention, a separating layer is provided on the dielectric layer, and an inner electrode made of a metal or a metal compound, which inner electrode extends over the collar region and the active region, is provided in the hole trench.

The method according to one embodiment of the invention provides a separating layer on the dielectric layer separating the inner electrode and the outer electrode of the trench capacitor from one another. Said separating layer is provided as a barrier layer that inhibits a damaging interaction between the inner electrode and the dielectric layer. An interaction that damages the dielectric is, by way of example, a chemical reaction between the metal and the oxide of the dielectric. The provision of the separating layer makes it possible to provide the inner electrode both in the active region and in the collar region of the trench capacitor from a metal or a metal compound without the dielectric being impaired by a chemical reaction with the metal, by restructuring processes, or by mechanical stresses in the metal.

The method according to one embodiment of the invention enables a low-impedance inner electrode made of metal or a metal compound to be introduced in a simple manner by the provision of the separating layer, which in one case is applied by means of a standard—CVD (Chemical Vapor Deposition)—process. In the case of this method, the electrical resistance is reduced to an extent similar to that in the case of a pure metal filling of the hole trench, without a separating layer. By virtue of the separating layer, which effects a spatial separation between the dielectric and the metal, the metal is not in direct contact with the dielectric and does not influence the quality of the dielectric.

One embodiment of the method has the simple capability of integrating the process steps required for the application of the separating layer into existing process sequences. The method is compatible with the various processings for a connection of the inner electrode to an assigned selection transistor, for instance a single- or double-sided buried strap formation made of metal of polysilicon. A low-impedance inner electrode affords a faster access time, thereby significantly increasing the performance of semiconductor memory devices. Also, a trench capacitor with a low-impedance inner electrode has better scalability of the trench capacitor, which is possible down to far less than minimum feature sizes of 100 nm and, at the same time, ensures a low lead resistance with respect to the capacitance.

In one embodiment, the inner electrode is provided on the insulation layer in the collar region and on the separating layer in the active region.

The hole trench is extended in a bottle-like manner in the active region. The bottle-like extension of the hole trench in the active region has a capacitance that is proportional to the electrode area can thereby be increased. Moreover, the process implementation according to one embodiment of the invention is simplified by means of a bottle-like extension of the hole trench, because the application of the separating layer becomes a self-aligning process by virtue of the smaller diameter of the collar region in comparison with the active region.

In one embodiment, the bottle-like extension of the hole trench in the active region is performed by means of a wet etching process.

A material for the separating layer is deposited conformally at least in the collar region and in the active region of the hole trench and the material is removed again from the collar region. The conformal deposition process may be, for example, a standard—CVD (Chemical Vapor Deposition)—process. Such a process for applying the separating layer is a quasi self-aligning process. Material is deposited conformally in the active region until the collar region is completely filled with material. Since the collar region grows over more rapidly than the active region, particularly if the active region has been extended in a bottle-like manner, the active region is not completely filled. A layer having a specific thickness and a cavity form in the active region. The material is removed again from the collar region by means of an isotropic etching process effected selectively with respect to the insulation layer.

In one embodiment, the separating layer is provided with a thickness in the range of 5 nm to 100 nm. A thickness in this range ensures that no interactions take place between the metal of the inner electrode and the dielectric layer. As already explained above, the thickness of the separating layer depends, inter alia, on the dimensions of the hole trench, for instance on the ratio of a diameter of the collar region to the diameter of the active region.

In one embodiment, doped polycrystalline or amorphous silicon is provided as material for the separating layer. By way of example, phosphorus- or arsenic-doped polycrystalline or amorphous silicon can be applied to the dielectric layer in a simple manner and has the property of preventing interactions that damage the dielectric.

In one embodiment, the material of the inner electrode is deposited conformally both in the collar region and in the active region.

The inner electrode is etched back in sections by means of an isotropic dry or wet etching process in the upper region. The etching-back of the inner electrode in the collar region is expedient in order to create space for a structure for making contact with the inner electrode.

A trench capacitor according to one embodiment of the invention is oriented to a hole trench introduced in a semiconductor substrate. The hole trench has an active region reaching into the semiconductor substrate and a collar region arranged between a substrate surface and the active region. An outer electrode is provided in sections of the semiconductor substrate that adjoin the hole trench. The hole trench is lined with a dielectric layer in the active region and with an insulation layer in the collar region. An inner electrode comprising a metal or a metal compound in sections is provided in the interior of the hole trench. According to one embodiment of the invention, a separating layer is provided between the dielectric layer and the inner electrode. In this case, the inner electrode, which extends over the collar region and the active region, is provided from a metal or a metal compound.

The inner electrode of the trench capacitor according to one embodiment of the invention is formed from a low-impedance material such as metal or a metal compound both in the collar region and in the active region, the separating layer effecting a separation of inner electrode and dielectric. The separating layer is provided as a barrier layer that inhibits damaging interactions between the inner electrode and the dielectric layer. This prevents the dielectric from being damaged by chemical interactions between the metal and the dielectric. With the trench capacitor according to one embodiment of the invention, the resistance of the inner electrode is reduced to the same extent as in the case of a pure metal filling of the hole trench, without a separating layer. A low-impedance inner electrode results in a faster read/write time, thereby significantly increasing the performance of semiconductor memory devices. Also, trench capacitor with a low-impedance inner electrode has better scalability of the trench capacitor, which is possible down to far less than minimum feature sizes of 100 nm and, in the process, ensures a low lead resistance with respect to the capacitance.

In one embodiment, the inner electrode is provided on the insulation layer in the collar region and on the separating layer in the active region. The cavity in the hole trench is completely filled with the metal or the metal compound of the inner electrode.

In one embodiment, the inner electrode is caused to recede in the collar region, in a section adjoining the substrate surface. This is expedient in order to create space for a structure which makes contact with the inner electrode.

The hole trench is extended in a bottle-like manner in the active region. A bottle-like extension increases the capacitance that depends on the area of the inner electrode in the active region.

In one embodiment, the separating layer is provided with a thickness in the range of 5 nm to 100 nm.

In one embodiment, doped polycrystalline or amorphous silicon is provided as material for the separating layer. By way of example, phosphorus- or arsenic-doped polycrystalline or amorphous silicon does not enter into any interactions with the dielectric layer. Moreover, polycrystalline or amorphous silicon can be applied in a simple manner by means of a standard CVD process.

A memory cell has a trench capacitor, which is connected to a selection transistor and stores a digital information item in the form of a charge state. The trench capacitor according to one embodiment of the invention is provided in the memory cell. The memory cell with the trench capacitor has a significantly reduced resistance with respect to the capacitance and thus a higher performance. Moreover, memory cells with the trench capacitor according to one embodiment of the invention can be scaled better. As a result, changes to the design are not necessary in the event of a transition to smaller feature sizes.

A memory device is provided with a memory cell that stores a digital information item. The memory device has at least one memory cell according to one embodiment of the invention with a trench capacitor. The memory device having memory cells with trench capacitors according to one embodiment of the invention has an accelerated read/write process and thus an increased performance. Moreover, memory cells with the trench capacitor according to one embodiment of the invention can be miniaturized to a greater extent, whereby achieving a higher integration density and thus a higher storage capacity of the memory device.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts:

FIGS. 1A-1D illustrate diagrammatic cross sections through a trench capacitor in different stages of an exemplary embodiment of the method according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In order to fabricate a trench capacitor 1 in a semiconductor substrate 10, a hole trench 2 is introduced into the semiconductor substrate 10 from a substrate surface 11. An outer electrode is provided, for example as a “buried plate”, in sections adjoining the hole trench 2 in the semiconductor substrate 10, for example by doping a zone in the semiconductor substrate 10. The hole trench 2 has an active region 13, which reaches into the semiconductor substrate 10 and is lined with a dielectric layer 5. By way of example, metal oxides and the oxides of rare earths, such as AL₂O₃, HfO₂, ZrO₂, La₂O₃, may be provided for the dielectric layer 5. A collar region 12 is situated between the substrate surface 11 and the active region 13. In this exemplary embodiment of the method according to one embodiment of the invention, a silicon nitride layer 9 is provided on the semiconductor substrate 10, which in this case comprises crystalline silicon. The silicon nitride layer 9 serves as a protective and etching stop layer. The collar region 12 is lined with an insulation layer 7 comprising silicon dioxide. A separating layer 6 made of amorphous silicon is applied to the dielectric layer 5 by means of a standard CVD process.

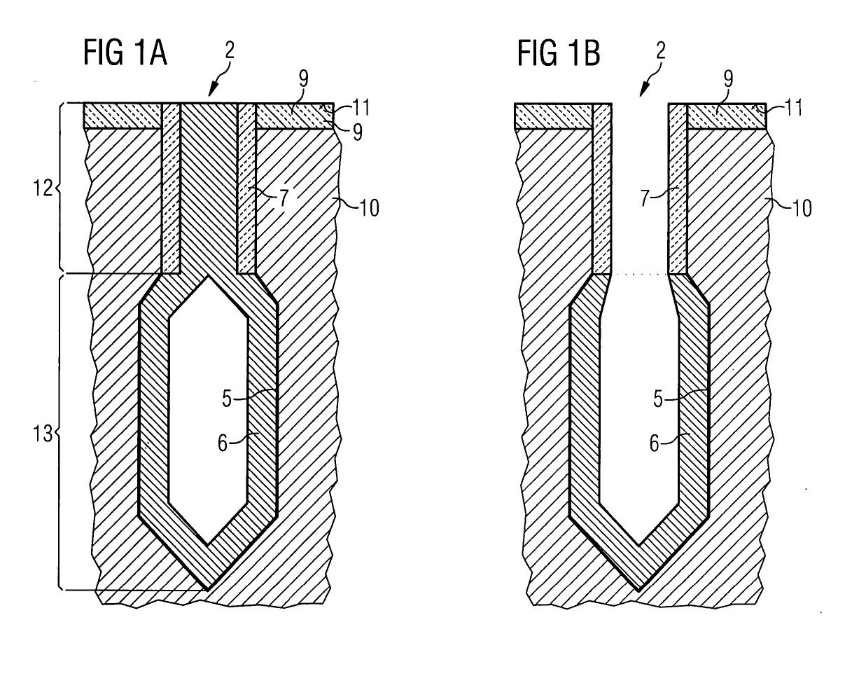

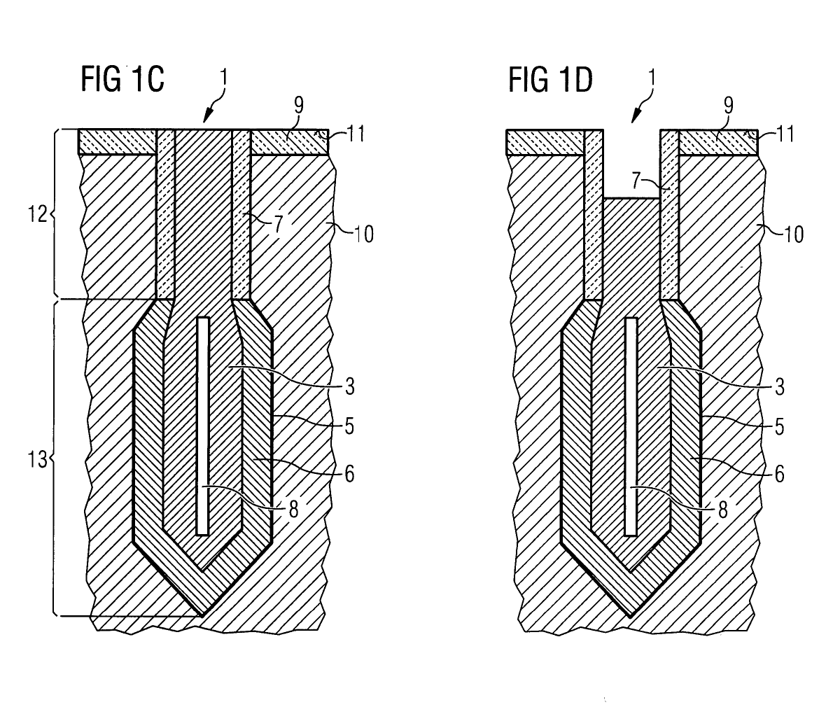

FIG. 1A illustrates the hole trench 2 in the semiconductor substrate 10 with an overlying silicon nitride layer 9. The hole trench 2 is subdivided into the collar region 12 adjoining the substrate surface 11 and the active region 13 reaching into the semi-conductor substrate 10. The dielectric layer 5 is provided on the trench walls in the active region 13. The insulation layer 7 is provided in the collar region 12. The separating layer 6 is represented after application by a deposition process and after a subsequent planarization step at the substrate surface 11. The collar region 12 of the hole trench 2 is completely filled with the amorphous silicon of the separating layer 6. A cavity is produced in the active region 13. The separating layer 6 has a thickness of approximately 5 nm to 100 nm in the active region 13, depending on the dimensions of the hole trench 2 and the process implementation.

In the collar region 12, the amorphous silicon of the separating layer 6 is caused to recede by means of an isotropic etching process effected selectively with respect to the insulator layer 7 and with respect to the silicon nitride layer 9.

The hole trench 2 after the etching-back of the amorphous silicon in the collar region 12 is illustrated in FIG. 1B. In contrast to FIG. 1A, the amorphous silicon as separating layer 6 is situated only in the active region of the hole trench 2.

The cavities produced in the active region 13 and in the collar region 12 are filled with a metal or a metal compound. The metal may be deposited conformally by means of a CVD or ALD (Atomic Layer Deposition) process. The deposited metal or the metal compound forms an inner electrode 3 of the trench capacitor 1. Possible materials for the inner electrode 3 are for example tungsten nitride, tantalum nitride, titanium nitride. However, other metals or metal compounds or layer systems comprising metals or metal compounds are also possible.

FIG. 1C illustrates the trench capacitor 1 filled with the inner electrode 3. The inner electrode 3, comprising a metal or a metal compound, completely fills the collar region 12 and the active region 13 apart from a narrow gap 8 in the active region 13. The narrow gap 8 results if the collar region 12 of the hole trench 2 grows over more rapidly than the active region 13. However, the narrow gap 8 is not important for the functionality of the inner electrode 3.

In a further process step, the inner electrode 3 is etched back again in sections in the collar region 12 of the hole trench 2. This may be effected by means of a dry etching process or by means of a wet etching process. The etching-back of the inner electrode 3 in the collar region 12 is expedient in order to be able to form the contacts to the inner electrode 3.

FIG. 1D differs from FIG. 1C by virtue of the inner electrode 3 that has been caused to recede by means of the etching-back.

Once the trench capacitor 1 has been processed in the manner described, the conductive connections to the selection transistor may subsequently be formed by means of a conventional standard processing. Usually, the conductive connections are provided as buried doped zones below the substrate surface 11. The buried conductive connections or “buried straps” are formed either in double-sided fashion with polysilicon or in double-sided fashion with metal or in single-sided fashion with either polysilicon or metal.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for fabricating a trench capacitor in a semiconductor substrate, comprising:
introducing a hole trench into the semiconductor substrate from a substrate surface and providing an outer electrode in sections of the semiconductor substrate that join the hole trench;
lining the hole trench with a dielectric layer in an active region reaching into the semiconductor substrate and arranging an insulation layer in a collar region between the substrate surface and the active region;
providing a separating layer on the dielectric layer; and
providing an inner electrode extending over the collar region and the active region in the hole trench.

2. The method of claim 1, wherein the inner electrode is made of one of the group comprising a metal and a metal compound.

3. The method of claim 1, wherein the separating layer is provided as a barrier layer that inhibits damaging interactions between the inner electrode and the dielectric layer.

4. The method of claim 3, wherein the inner electrode is provided on the insulation layer in the collar region and on the separating layer in the active region.

5. The method of claim 1, wherein the hole trench is extended in a bottle-like manner in the active region.

6. The method of claim 5, wherein the bottle-like extension of the hole trench in the active region is performed by means of a wet etching process.

7. The method of claims 1, wherein for the provision of the separating layer, a material for the separating layer is deposited conformally at least in the collar region and in the active region of the hole trench and then the material is removed from the collar region.

8. The method of claim 1, wherein the separating layer is provided with a thickness in the range of 5 nanometers to 100 nanometers.

9. The method of claims 1, wherein doped polycrystalline or amorphous silicon is provided as material for the separating layer.

10. The method of claim 1, wherein the inner electrode is deposited conformally.

11. The method of claim 1, wherein the inner electrode is etched back in sections by means of an isotropic dry or wet etching process in the upper region.

12. A trench capacitor oriented to a hole trench introduced in a semiconductor substrate, comprising:
an active region of the hole trench reaching into the semiconductor substrate and a collar region arranged between a substrate surface and the active region;
an outer electrode provided in sections that adjoin the hole trench in the active region of the semiconductor substrate;
a dielectric layer lining the hole trench in the active region and with an insulation layer in sections in the collar region;
an inner electrode in sections being provided in the interior of the hole trench;
a separating layer provided on the dielectric layer; and
wherein the inner electrode extends over the collar region and the active region.

13. The trench capacitor of claim 12, wherein the inner electrode is provided of one of the group comprising metal and metal compound.

14. The trench capacitor of claim 12, wherein the separating layer is provided as a barrier layer that inhibits damaging interactions between the inner electrode and the dielectric layer.

15. The trench capacitor of claim 14, wherein the inner electrode is provided on the insulation layer in the collar region and on the separating layer in the active region.

16. The trench capacitor of claim 12, wherein the inner electrode is caused to recede in sections in the collar region.

17. The trench capacitor of claim 12, wherein the hole trench is extended in a bottle-like manner in the active region.

18. The trench capacitor of claim 12, wherein the separating layer is provided with a thickness in the range of 5 nanometers to 100 nanometers.

19. The trench capacitor of claim 12, wherein the separating layer is provided from doped polycrystalline or amorphous silicon.

20. The trench capacitor of claim 12 that stores a digital information item in the form of a charge state and is connected to a selection transistor, the trench capacitor being part of a memory cell.

21. The trench capacitor of claim 20, wherein the memory cell is part of a memory device having multiple memory cells that store a digital information item.

22. A method for fabricating a trench capacitor in a semiconductor substrate, comprising:
introducing a hole trench into the semiconductor substrate from a substrate surface and providing an outer electrode in sections of the semiconductor substrate that join the hole trench;
lining the hole trench with a dielectric layer in an active region reaching into the semiconductor substrate and arranging an insulation layer in a collar region between the substrate surface and the active region, wherein the hole trench is extended in a bottle-like manner in the active region;
providing a separating layer on the dielectric layer in the active region; and
providing an inner electrode extending over the collar region and active region in the hole trench, the inner electrode completely filling the hole trench in the active region except for a narrow gap.

23. The method of claim 22, wherein the inner electrode is provided of one of the group comprising metal and metal compound.

24. A trench capacitor oriented to a hole trench introduced in a semiconductor substrate, comprising:
an active region of the hole trench reaching into the semiconductor substrate and a collar region arranged between a substrate surface and the active region;
an outer electrode provided in sections that adjoin the hole trench in the active region of the semiconductor substrate;
a dielectric layer lining the hole trench in the active region and with an insulation layer in sections in the collar region;
an inner electrode at least in sections being provided in the interior of the hole trench, wherein the hole trench is extended in a bottle-like manner in the active region;
providing a separating layer on the dielectric layer in the active region; and
wherein the inner electrode extends over the collar region and the active region, the inner electrode completely filling the hole trench in the active region except for a narrow gap.

25. The trench capacitor of claim 24, wherein the inner electrode is provided of one of the group comprising metal and metal compound.
